(19) United States
(12) Patent Application Publication
(10) Pub. No.: US 2025/0069631 A1
(43) Pub. Date: Feb. 27, 2025

(54) DATA ALIGNMENT FOR MEMORY

(71) Applicant: Micron Technology, Inc., Boise, ID (US)

(72) Inventors: Martin Bach, München (DE); Miljana Nenadovic, München (DE); Hemant Madhewar, München (DE); Mani Balakrishnan, München (DE); Thomas Hein, München (DE); Martin Brox, München (DE)

(21) Appl. No.: 18/771,448

(22) Filed: Jul. 12, 2024

Related U.S. Application Data
(60) Provisional application No. 63/534,512, filed on Aug. 24, 2023.

(51) Int. Cl. G11C 7/22; G11C 7/10

(52) U.S. Cl. CPC G11C 7/222; G11C 7/1066; G11C 7/1072

(57) ABSTRACT

Methods, systems, and devices for data alignment for memory are described. A memory device may implement individual time adjustments to align portions of a multilevel signal modulated by a modulation scheme with three levels. In some cases, signal paths for generating and transmitting the portions of the multilevel signal may reference a clock signal, and adjustable delay circuits may apply individual delays to the clock signal received at each signal path. For example, a first adjustable delay circuit may apply a first time adjustment to the clock signal received at a first signal path for generating a first portion. And, a second adjustable delay circuit may apply a second time adjustment to the clock signal received at a second signal path for generating a second portion. Applying the time adjustments to the signal paths may align the portions of the multilevel signal in time, compared to the clock signal.

### CROSS REFERENCE

The present Application for Patent claims priority to U.S. Patent Application No. 63/534,512 by Bach et al., entitled “DATA ALIGNMENT FOR MEMORY,” filed Aug. 24, 2023, which is assigned to the assignee hereof, and which is expressly incorporated by reference in its entirety herein.

### TECHNICAL FIELD

The following relates to one or more systems for memory, including data alignment for memory.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells in a non-volatile configuration may maintain stored logic states for extended periods of time even in the absence of an external power source. Memory cells in a volatile configuration may lose stored states when disconnected from an external power source.

### BRIEF DESCRIPTION OF THE DRAWINGS

FIG. 1 shows an example of a system that supports data alignment for memory in accordance with examples as disclosed herein.

FIG. 2 shows an example of a signaling circuit that supports data alignment for memory in accordance with examples as disclosed herein.

FIGS. 3A and 3B show examples of a multilevel signaling diagram that supports data alignment for memory in accordance with examples as disclosed herein.

FIG. 4 shows a block diagram of a memory device that supports data alignment for memory in accordance with examples as disclosed herein.

FIG. 5 shows a flowchart illustrating a method or methods that support data alignment for memory in accordance with examples as disclosed herein.

### DETAILED DESCRIPTION

In some cases, a memory device (e.g., or a host device) may generate a multilevel signal (e.g., a signal modulated with a modulation scheme with three or more distinct amplitude levels) for communicating information (e.g., one or more bits of information). However, in some such cases, during generating the multilevel signal, portions (e.g., subeyes between two levels of the multilevel signal) of the multilevel signal may become misaligned from other portions (e.g., subeyes). For example, some multilevel signal paths may include two or more signaling components (e.g., each including a serialization component and a driver) each associated with generating and transmitting (e.g., driving) a respective portion (e.g., each signaling component associated with signal transitions between two levels) of the multilevel signal. Yet, a timing of the two or more signaling components may become misaligned, resulting in misaligned portions of the multilevel signal. This may occur during serializing data to generate the portions of the multilevel signal, or assembling the portions of the multilevel signal for transmission, such that the serializing (e.g., differences in the time to serialize at each signaling component) or the assembling may cause the portions to become misaligned in time (e.g., when compared to a clock signal). In some implementations, misalignment between portions of the multilevel signal may decrease a signal to noise ratio (SNR) or increase a bit error rate (BER), or both, of the multilevel signal, which may limit a transmission speed of the multilevel signal. Additionally, misalignment between portions of the multilevel signal may cause difficulty during reading the signal (e.g., due to misaligned sampling points of the portions), among other disadvantages.

In accordance with examples as described herein, a memory device may implement individual time adjustments (e.g., delays) to align portions of a multilevel signal generated using different signal paths (e.g., signal chains). In some cases, signal paths associated with generating and transmitting the portions of the multilevel signal may reference a clock signal, and the memory device may apply individual time adjustments to the clock signal received at each signal path. For example, the memory device (e.g., a first adjustable delay circuit) may apply a first time adjustment to the clock signal received at a first signal path associated with generating a first portion of the multilevel signal. And, the memory device (e.g., a second adjustable delay circuit) may apply a second time adjustment to the clock signal received at a second signal path associated with generating a second portion of the multilevel signal. In some cases, applying the first time adjustment and the second time adjustment may align the generating and assembling of the first portion and the second portion of the multilevel signal, such that the first portion and the second portion of the multilevel signal may be aligned in time (e.g., compared to the clock signal). Aligning the portions of the multilevel signal may increase a SNR and decrease a BER of the multilevel signal, thereby supporting relatively higher transmission speed of the multilevel signal (e.g., compared to previous implementations). Additionally, aligning the portions of the multilevel signal may prevent difficulties during reading the signal (e.g., due to aligned sampling points of the portions), among other advantages.

Features of the disclosure are illustrated and described in the context of systems, a signaling circuit, and multilevel signaling diagrams. Features of the disclosure are further illustrated and described in the context of a block diagram and a flowchart.

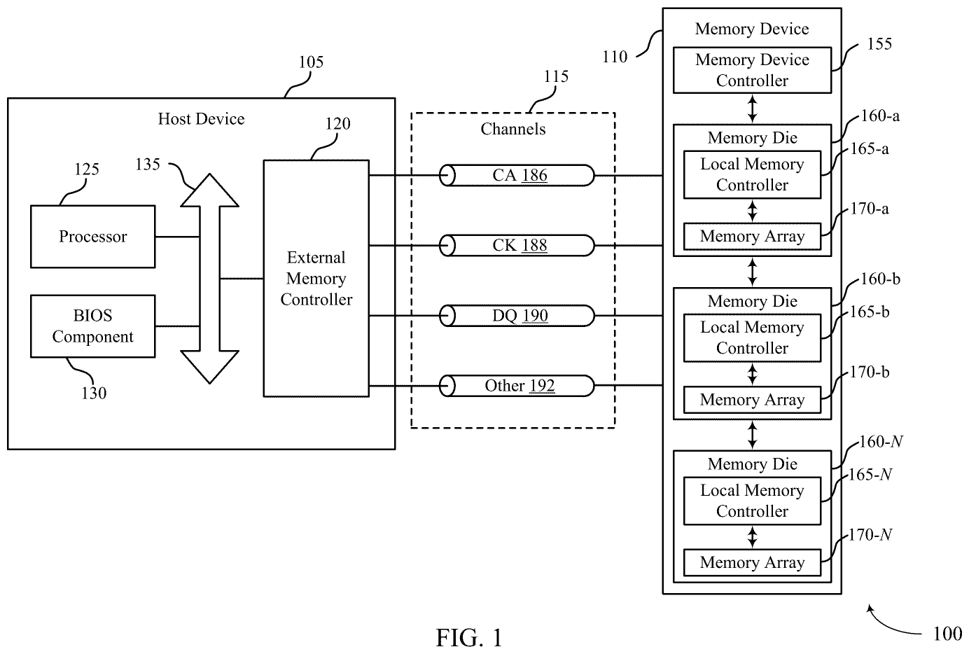

FIG. 1 shows an example of a system 100 that supports data alignment for memory in accordance with examples as disclosed herein. The system 100 may include a host device 105, a memory device 110, and a plurality of channels 115 coupling the host device 105 with the memory device 110. The system 100 may include one or more memory devices 110, but aspects of the one or more memory devices 110 may be described in the context of a single memory device (e.g., memory device 110).

The system 100 may include portions of an electronic device, such as a computing device, a mobile computing device, a wireless device, a graphics processing device, a vehicle, or other systems. For example, the system 100 may illustrate aspects of a computer, a laptop computer, a tablet computer, a smartphone, a cellular phone, a wearable device, an internet-connected device, a vehicle controller, or the like. The memory device 110 may be a component of the system 100 that is operable to store data for one or more other components of the system 100.

Portions of the system 100 may be examples of the host device 105. The host device 105 may be an example of a processor (e.g., circuitry, processing circuitry, a processing component) within a device that uses memory to execute processes, such as within a computing device, a mobile computing device, a wireless device, a graphics processing device, a computer, a laptop computer, a tablet computer, a smartphone, a cellular phone, a wearable device, an internet-connected device, a vehicle controller, a system on a chip (SoC), or some other stationary or portable electronic device, among other examples. In some examples, the host device 105 may refer to the hardware, firmware, software, or any combination thereof that implements the functions of an external memory controller 120. In some examples, the external memory controller 120 may be referred to as a host (e.g., host device 105).

A memory device 110 may be an independent device or a component that is operable to provide physical memory addresses/space that may be used or referenced by the system 100. In some examples, a memory device 110 may be configurable to work with one or more different types of host devices. Signaling between the host device 105 and the memory device 110 may be operable to support one or more of: modulation schemes to modulate the signals, various pin configurations for communicating the signals, various form factors for physical packaging of the host device 105 and the memory device 110, clock signaling and synchronization between the host device 105 and the memory device 110, timing conventions, or other functions.

The memory device 110 may be operable to store data for the components of the host device 105. In some examples, the memory device 110 (e.g., operating as a secondary-type device to the host device 105, operating as a dependent-type device to the host device 105) may respond to and execute commands provided by the host device 105 through the external memory controller 120. Such commands may include one or more of a write command for a write operation, a read command for a read operation, a refresh command for a refresh operation, or other commands.

The host device 105 may include one or more of an external memory controller 120, a processor 125, a basic input/output system (BIOS) component 130, or other components such as one or more peripheral components or one or more input/output controllers. The components of the host device 105 may be coupled with one another using a bus 135.

The processor 125 may be operable to provide functionality (e.g., control functionality) for the system 100 or the host device 105. The processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination of these components. In such examples, the processor 125 may be an example of a central processing unit (CPU), a graphics processing unit (GPU), a general purpose GPU (GPGPU), or an SoC, among other examples. In some examples, the external memory controller 120 may be implemented by or be a part of the processor 125.

The BIOS component 130 may be a software component that includes a BIOS operated as firmware, which may initialize and run various hardware components of the system 100 or the host device 105. The BIOS component 130 may also manage data flow between the processor 125 and the various components of the system 100 or the host device 105. The BIOS component 130 may include instructions (e.g., a program, software) stored in one or more of read-only memory (ROM), flash memory, or other non-volatile memory.

In some examples, the system 100 or the host device 105 may include various peripheral components. The peripheral components may be any input device or output device, or an interface for such devices, that may be integrated into or with the system 100 or the host device 105. Examples may include one or more of: a disk controller, a sound controller, a graphics controller, an Ethernet controller, a modem, a universal serial bus (USB) controller, a serial or parallel port, or a peripheral card slot such as peripheral component interconnect (PCI) or specialized graphics ports. The peripheral component(s) may be other components understood by a person having ordinary skill in the art as a peripheral.

In some examples, the system 100 or the host device 105 may include an input component, an output component, or both. An input component may represent a device or signal external to the system 100 that provides information (e.g., signals, data) to the system 100 or its components. In some examples, and input component may include an interface (e.g., a user interface or an interface between other devices). In some examples, an input component may be a peripheral that interfaces with system 100 via one or more peripheral components or may be managed by an I/O controller. An output component may represent a device or signal external to the system 100 operable to receive an output from the system 100 or any of its components. Examples of an output component may include a display, audio speakers, a printing device, another processor on a printed circuit board, and others. In some examples, an output may be a peripheral that interfaces with the system 100 via one or more peripheral components or may be managed by an I/O controller.

The memory device 110 may include a memory device controller 155 and one or more memory dies 160 (e.g., memory chips) to support a capacity (e.g., a desired capacity, a specified capacity) for data storage. Each memory die 160 (e.g., memory die 160-a, memory die 160-b, memory die 160-N) may include a local memory controller 165 (e.g., local memory controller 165-a, local memory controller 165-b, local memory controller 165-N) and a memory array 170 (e.g., memory array 170-a, memory array 170-b, memory array 170-N). A memory array 170 may be a collection (e.g., one or more grids, one or more banks, one or more tiles, one or more sections) of memory cells, with each memory cell being operable to store one or more bits of data. A memory device 110 including two or more memory dies 160 may be referred to as a multi-die memory or a multi-die package or a multi-chip memory or a multi-chip package.

The memory device controller 155 may include components (e.g., circuitry, logic) operable to control operation of the memory device 110. The memory device controller 155 may include hardware, firmware, or instructions that enable the memory device 110 to perform various operations and may be operable to receive, transmit, or execute commands, data, or control information related to the components of the memory device 110. The memory device controller 155 may be operable to communicate with one or more of the external memory controller 120, the one or more memory dies 160, or the processor 125. In some examples, the memory device controller 155 may control operation of the memory device 110 described herein in conjunction with the local memory controller 165 of the memory die 160.

In some examples, the memory device 110 may communicate information (e.g., data, commands, or both) with the host device 105. For example, the memory device 110 may receive a write command indicating that the memory device 110 is to store data received from the host device 105, or receive a read command indicating that the memory device 110 is to provide data stored in a memory die 160 to the host device 105, among other types of information communication.

A local memory controller 165 (e.g., local to a memory die 160) may include components (e.g., circuitry, logic) operable to control operation of the memory die 160. In some examples, a local memory controller 165 may be operable to communicate (e.g., receive or transmit data or commands or both) with the memory device controller 155. In some examples, a memory device 110 may not include a memory device controller 155, and a local memory controller 165 or the external memory controller 120 may perform various functions described herein. As such, a local memory controller 165 may be operable to communicate with the memory device controller 155, with other local memory controllers 165, or directly with the external memory controller 120, or the processor 125, or any combination thereof. Examples of components that may be included in the memory device controller 155 or the local memory controllers 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, or various other components operable for supporting described operations of the memory device controller 155 or local memory controller 165 or both.

The external memory controller 120 may be operable to enable communication of information (e.g., data, commands, or both) between components of the system 100 (e.g., between components of the host device 105, such as the processor 125, and the memory device 110). The external memory controller 120 may process (e.g., convert, translate) communications exchanged between the components of the host device 105 and the memory device 110. In some examples, the external memory controller 120, or other component of the system 100 or the host device 105, or its functions described herein, may be implemented by the processor 125. For example, the external memory controller 120 may be hardware, firmware, or software, or some combination thereof implemented by the processor 125 or other component of the system 100 or the host device 105. Although the external memory controller 120 is depicted as being external to the memory device 110, in some examples, the external memory controller 120, or its functions described herein, may be implemented by one or more components of a memory device 110 (e.g., a memory device controller 155, a local memory controller 165) or vice versa.

The components of the host device 105 may exchange information with the memory device 110 using one or more channels 115. The channels 115 may be operable to support communications between the external memory controller 120 and the memory device 110. Each channel 115 may be an example of a transmission medium that carries information between the host device 105 and the memory device 110. Each channel 115 may include one or more signal paths (e.g., a transmission medium, a conductor) between terminals associated with the components of the system 100. A signal path may be an example of a conductive path operable to carry a signal. For example, a channel 115 may be associated with a first terminal (e.g., including one or more pins, including one or more pads) at the host device 105 and a second terminal at the memory device 110. A terminal may be an example of a conductive input or output point of a device of the system 100, and a terminal may be operable to act as part of a channel.

Channels 115 (and associated signal paths and terminals) may be dedicated to communicating one or more types of information. For example, the channels 115 may include one or more command and address (CA) channels 186, one or more clock signal (CK) channels 188, one or more data (DQ) channels 190, one or more other channels 192, or any combination thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols (e.g., signal levels) of a signal may be registered for each clock cycle (e.g., on both a rising edge and a falling edge of a clock signal).

In some examples, CA channels 186 may be operable to communicate commands between the host device 105 and the memory device 110 including control information associated with the commands (e.g., address information). For example, commands carried by the CA channel 186 may include a read command with an address of the desired data. In some examples, a CA channel 186 may include any quantity of signal paths (e.g., eight or nine signal paths) to communicate control information (e.g., commands or addresses).

In some examples, clock signal channels 188 may be operable to communicate one or more clock signals between the host device 105 and the memory device 110. Clock signals may be operable to oscillate between a high state and a low state, and may support coordination (e.g., in time) between actions of the host device 105 and the memory device 110. In some examples, the clock signal may be single ended. In some examples, the clock signal may provide a timing reference for command and addressing operations for the memory device 110, or other system-wide operations for the memory device 110. A clock signal may be referred to as a control clock signal, a command clock signal, or a system clock signal. A system clock signal may be generated by a system clock, which may include one or more hardware components (e.g., oscillators, crystals, logic gates, transistors).

In some examples, data channels 190 may be operable to communicate information (e.g., data, control information) between the host device 105 and the memory device 110. For example, the data channels 190 may communicate information (e.g., bi-directional) to be written to the memory device 110 or information read from the memory device 110.

The channels 115 may include any quantity of signal paths (including a single signal path). In some examples, a channel 115 may include multiple individual signal paths. For example, a channel may be x4 (e.g., including four signal paths), x8 (e.g., including eight signal paths), x16 (including sixteen signal paths), etc.

Signals communicated over the channels 115 may be modulated using one or more different modulation schemes. In some examples, a binary-symbol (or binary-level) modulation scheme may be used to modulate signals communicated between the host device 105 and the memory device 110. A binary-symbol modulation scheme may be an example of a M-ary modulation scheme where M is equal to two. A symbol of a binary-symbol modulation scheme may be operable to represent one bit of digital data (e.g., a symbol may represent a logic 1 or a logic 0). Examples of binary-symbol modulation schemes include, but are not limited to, non-return-to-zero (NRZ), unipolar encoding, bipolar encoding, Manchester encoding, pulse amplitude modulation (PAM) having two symbols (e.g., PAM2), and others.

In some examples, a multi-symbol (or multi-level) modulation scheme may be used to modulate signals communicated between the host device 105 and the memory device 110. A multi-symbol modulation scheme may be an example of a M-ary modulation scheme where M is greater than or equal to three. A symbol of a multi-symbol modulation scheme may be operable to represent more than one bit of digital data (e.g., a symbol may represent a logic 00, a logic 01, a logic 10, or a logic 11). Examples of multi-symbol modulation schemes include, but are not limited to, PAM3, PAM4, PAM8, etc., quadrature amplitude modulation (QAM), quadrature phase shift keying (QPSK), and others. A multi-symbol signal (e.g., a PAM3 signal or a PAM4 signal) may be a signal that is modulated using a modulation scheme that includes at least three levels to encode more than one bit of information. Multi-symbol modulation schemes and symbols may alternatively be referred to as non-binary, multi-bit, or higher-order modulation schemes and symbols.

In accordance with examples as described herein, the memory device 110 may implement individual time adjustments (e.g., delays) to align portions (e.g., subeyes between two levels) of a multilevel signal (e.g., a signal modulated by a modulation scheme with three or more distinct amplitude levels). In some cases, two or more signal paths may be used to generate (e.g., serializing) and transmit two or more portions of the multilevel signal. Each of the signal paths may reference the clock signal, and the memory device 110 may apply individual time adjustments to the clock signal received at each signal path. For example, the memory device 110 may apply a first time adjustment to the clock signal received at a first signal path associated with generating a first portion of the multilevel signal. And, the memory device 110 may apply a second time adjustment to the clock signal received at a second signal path associated with generating a second portion of the multilevel signal. In some cases, applying the first time adjustment and the second time adjustment may align the generating and assembling of the first portion and the second portion of the multilevel signal, such that the first portion and the second portion of the multilevel signal may be aligned in time (e.g., compared to the clock signal). Aligning the portions of the multilevel signal may increase a SNR and decrease a BER of the multilevel signal, thereby supporting relatively higher transmission speed of the multilevel signal (e.g., compared to previous implementations). Additionally, aligning the portions of the multilevel signal may prevent difficulties during reading the signal (e.g., due to aligned sampling points of the portions), among other advantages.

In addition to applicability in memory devices as described herein, techniques for data alignment for memory may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by aligning portions of a multilevel signal, which may improve data transfer between devices and enable increased communication between devices, among other benefits.

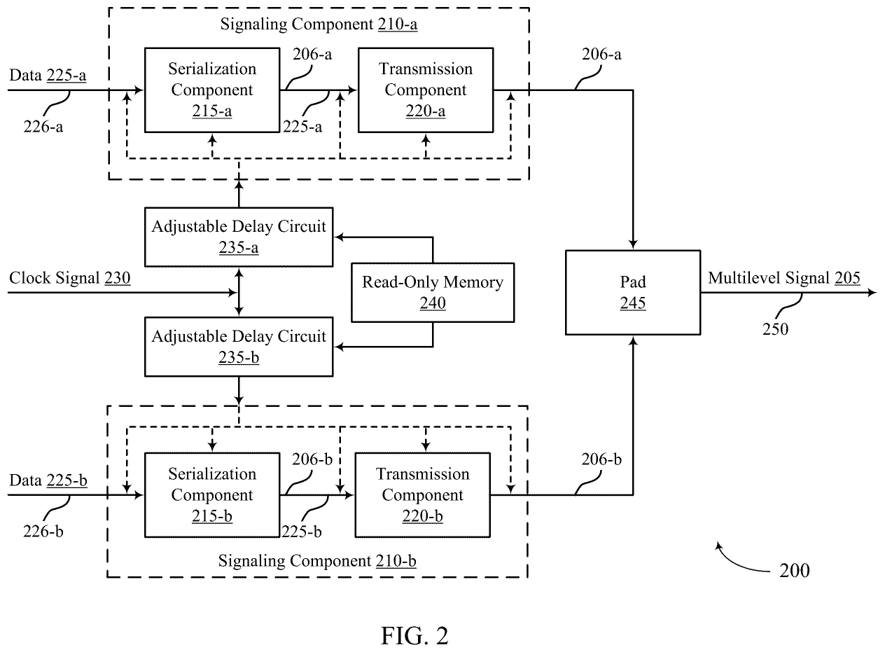

FIG. 2 shows an example of a signaling circuit 200 that supports data alignment for memory in accordance with examples as disclosed herein. The signaling circuit 200 may implement aspects or operations of a system 100 as described with reference to FIG. 1. For example, the signaling circuit 200 may be implemented at a memory device or a host device, which may be an example of a memory device 110 or a host device 105, respectively, as described with reference to FIG. 1. The signaling circuit 200 may be configured to generate, align, and transmit a multilevel signal 205 based on applying individual time adjustments to a clock signal received at signaling paths of the signaling circuit 200.

The signaling circuit 200 may be configured to generate and transmit a multilevel signal 205 which may be modulated according to a modulation scheme (e.g., PAM3) that includes three or more distinct amplitude levels (e.g., level −1, level 0, level 1), each associated with indicating a respective value of information (e.g., −1, 0, 1) over the multilevel signal 205. In some cases, the multilevel signal 205 may include two or more portions 206, where each portion 206 (e.g., subeye) is associated with transitions between two of the three or more distinct amplitude levels. The signaling circuit 200 may include, for example, two signaling paths (e.g., or more) each associated with generating and transmitting (e.g., driving) a respective portion 206 (e.g., a subeye) of the multilevel signal 205. For example, a first signaling path may be configured to generate and transmit a portion 206-a of the multilevel signal 205, such that the first signaling path may be associated with generating and transmitting the multilevel signal 205 at or transitioning between two (e.g., level 1, level 0) of the three or more distinct amplitude levels. In some such examples, a second signaling path may be configured to generate and transmit a portion 206-b of the multilevel signal 205, such that the second signaling path may be associated with generating and transmitting the multilevel signal 205 at or transitioning between another two (e.g., level 0, level −1) of the three or more distinct amplitude levels. Each of the first signaling path and the second signaling path may include similar components configured to perform similar operations for generating, aligning, and transmitting the respective portions 206 of the multilevel signal 205. For clarity and conciseness, the first signaling path is described herein, which may be exemplary of the second signaling path and include similar components.

The first signaling path may include a signaling component 210-a (e.g., a first signaling component) configured to generate and transmit the portion 206-a of the multilevel signal 205. The signaling component 210-a may include a serialization component 215-a (e.g., a first serialization component) and a transmission component 220-a (e.g., a first driver). The serialization component 215-a may be configured to serialize data 225-a received at the serialization component 215-a via one or more signals. In some examples, the data 225-a may be transmitted to the serialization component 215-a via one or more data lines 226-a, which may be examples of data channels 190, as described with reference to FIG. 1. In some cases, serializing the data 225-a may include converting the data 225-a from a parallel input into a serial output. In some cases, serializing the data 225-a may be associated with generating the portion 206-a of the multilevel signal 205, such that the portion 206-a of the multilevel signal 205 includes the serialized data 225-a. For example, the serialization component 215-a may be configured to generate the portion 206-a (e.g., including the serialized data 225-a) and transmit the portion 206-a to the transmission component 220-a . However, in other cases, after serializing the data 225-a, the serialization component 215-a may transmit the serialized data 225-a to the transmission component 220-a. The transmission component 220-a may be configured to transmit (e.g., drive) the portion 206-a to a pad 245 of the signaling circuit 200. In some cases, the transmission component 220-a may be configured to assemble the serialized data 225-a received from the serialization component 215-a into the portion 206-a, then transmit the portion 206-a to the pad 245. The pad 245 may be a contact (e.g., an electrode) coupled with a conductive path 250 configured to carry the multilevel signal 205 (e.g., to a receiver).

The first signaling path may also include an adjustable delay circuit 235-a coupled with the signaling component 210-a. The adjustable delay circuit 235-a may be configured to apply a time adjustment (e.g., a first time adjustment) to a clock signal 230. The clock signal 230 may be provide a time reference for operations of the signaling component 210-a, such that the serialization component 215-a and the transmission component 220-a may each perform the operations described herein according to the clock signal 230. In some examples, the clock signal may be received at the adjustable delay circuit 235-b via one or more clock signal lines, which may be examples of clock signal channels 188, as described with reference to FIG. 1. In some cases, applying the time adjustment to the clock signal 230 may delay one or more operations performed by the signaling component 210-a, such as generating and transmitting the portion 206-a. In some such cases, applying the time adjustment to the clock signal 230 may delay a timing of the portion 206-a within the resulting multilevel signal 205. For example, the signaling component 210-a may be associated with an inherent delay for performing the operations associated with generating and transmitting the portion 206-a and the time adjustment may provide an additional delay for aligning a timing of the portion 206-a and the portion 206-b. In some examples, the time adjustment may be applied to the signaling component 210-a before the serialization component 215-a, at the serialization component 215-a, after the serialization component 215-a but before the transmission component 220-a, at the transmission component 220-a, or after the transmission component 220-a, or any combination thereof.

In some cases, the time adjustment may be associated with an indication (e.g., a value) stored in a read-only memory 240. In some such cases, the indication may be stored in one or more one-time programmable memory elements (e.g., a fuse, an antifuse) of the read-only memory 240. In some examples, applying the time adjustment may include accessing the read-only memory 240 to identify the indication and transmitting the indication to the adjustable delay circuit 235-a, such that the adjustable delay circuit 235-a may apply the time adjustment associated with the indication. In some cases, the indication may be determined prior to storing the indication in the read-only memory 240. In some such cases, determining the indication may include measuring a misalignment (e.g., a difference) in timing between the portion 206-a and the portion 206-b of the multilevel signal. The indication may be generated based on determining a delay that may be applied to the signaling component 210-a to align the timing of the portion 206-a and 206-b (e.g., based on measuring the misalignment).

Similarly, the second signaling path may include a signaling component 210-b (e.g., a second signaling component) configured to generate and transmit the portion 206-b of the multilevel signal 205. The signaling component 210-b may include a serialization component 215-b (e.g., a second serialization component) and a transmission component 220-b (e.g., a second driver). The serialization component 215-b may be configured to serialize data 225-b received via one or more data lines 226-b. In some cases, the serialization component 215-b may be configured to generate the portion 206-b and transmit the portion 206-b, or the serialized data 225-b, to the transmission component 220-b. The transmission component 220-b may be configured to transmit (e.g., drive) the portion 206-b to the pad 245, or assemble the serialized data 225-b into the portion 206-b, then transmit the portion 206-b to the pad 245. The second signaling path may also include an adjustable delay circuit 235-b configured to apply a time adjustment (e.g., a second time adjustment) to the clock signal 230. In some such cases, applying the time adjustment may delay a timing of the portion 206-b within the resulting multilevel signal 205. The time adjustment may be associated with an indication (e.g., a value) stored in one or more of the one-time programmable memory elements of the read-only memory 240 and applying the time adjustment may include accessing, by the adjustable delay circuit 235-b, the indication in the read-only memory 240. The indication may be generated based on determining a delay that may be applied to the signaling component 210-b to align the timing of the portion 206-a and 206-b (e.g., based on measuring the misalignment).

A process for operating the signaling circuit 200 may be described herein. The process may include identifying (e.g., receiving) the data 225-a and the data 225-b at the serialization component 215-a and the serialization component 215-b, respectively. The process may include concurrently receiving the clock signal 230 at both the adjustable delay circuit 235-a and the adjustable delay circuit 235-b. In some cases, the adjustable delay circuit 235-a may apply a first time adjustment to the clock signal 230 (e.g., generating a first time adjusted clock signal 230), and/or the adjustable delay circuit 235-b may apply a second time adjustment to the clock signal 230 (e.g., generating a second time adjusted clock signal 230). In some such cases, the adjustable delay circuit 235-a may transmit the first time adjusted clock signal 230 to the signaling component 210-a, and the adjustable delay circuit 235-b may transmit the second time adjusted clock signal 230 to the signaling component 210-b. Then, the serialization component 215-a may serialize the data 225-a to generate the portion 206-a based on the first time adjusted clock signal 230. Similarly, the serialization component 215-b may serialize the data 225-b to generate the portion 206-b based on the second time adjusted clock signal 230. After generating the portions 206-a and 206-b, the transmission component 220-a and the transmission component 220-b may transmit the respective portions 206 to the pad 245 based on the respective time adjustments. Finally, the pad 245 may transmit the multilevel signal 205 along the conductive path 250 to a receiver, where the receiver may read the multilevel signal 205.

In accordance with examples as described herein, applying individual time adjustments to each signal path may align (e.g., in time) the portion 206-a and the portion 206-b of the multilevel signal 205. For example, each signaling component 210 may be associated with an inherent latency for generating and transmitting the respective portions 206 of the multilevel signal 205. However, applying the time adjustments may align the timing of the portion 206-a and the portion 206-b, such that the inherent latency of each signaling component 210 may not misalign the multilevel signal 205. In some cases, aligning the portions 206 of the multilevel signal 205 may support an increased SNR and a decreased BER, which may support increased transmission speed of the multilevel signal 205 (e.g., compared to previous implementations). Additionally, aligning the portions 206 of the multilevel signal 205 may improve reading the multilevel signal 205 at the receiver of the multilevel signal 205 due to aligned read windows of the portions 206 of multilevel signal 205.

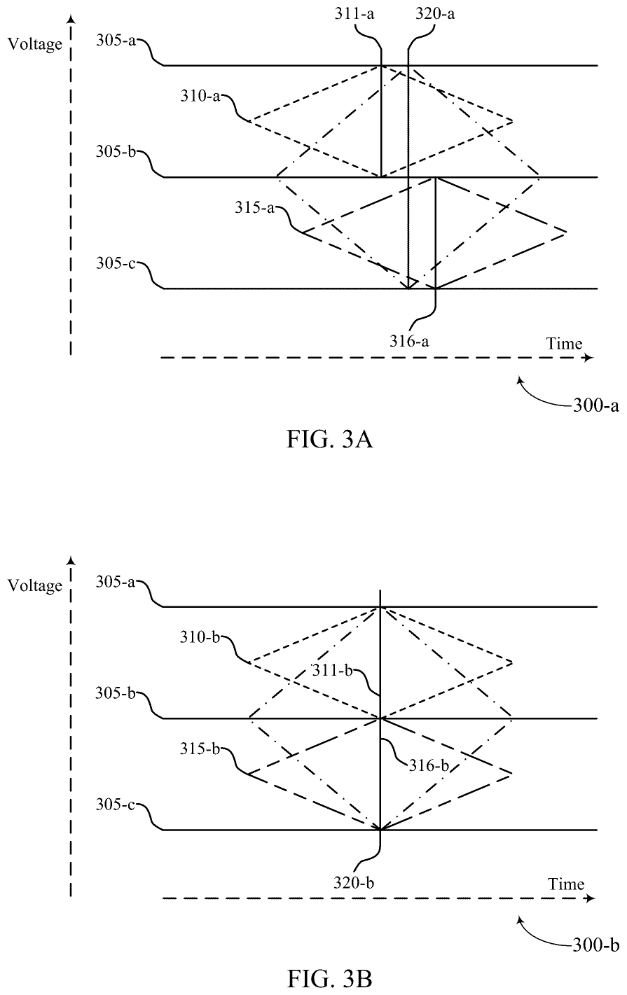

FIGS. 3A and 3B show examples of multilevel signaling diagrams 300-a and 300-b that support data alignment for memory in accordance with examples as disclosed herein. The multilevel signaling diagrams 300-a and 300-b may each implement aspects or show operations of a signaling circuit 200 as described with reference to FIG. 2. For example, the multilevel signaling diagrams 300-a and 300-b illustrate read windows (e.g., sometimes referred to as eyes or subeyes) for a multilevel signal and portions of the multilevel signal, which may be examples of a multilevel signal 205 and portions 206-a and 206-b, respectively, as described with reference to FIG. 2. Specifically, the multilevel signaling diagram 300-a illustrates read windows for a multilevel signal generated without individual time adjustments applied to the portions of the multilevel signal (e.g., as in previous implementations). However, the multilevel signaling diagram 300-b illustrates read windows for the multilevel signal 205 generated based on applying individual time adjustments to the portions 206 of the multilevel signal 205.

The multilevel signaling diagrams 300-a and 300-b each depict a multilevel signal modulated using a modulation scheme including three levels 305 (e.g., PAM3), which may be distinct amplitude levels of voltage. For example, the three levels 305 may include a level 305-a (e.g., level 1), a level 305-b (e.g., level 0), and a level 305-c (e.g., level −1), where each level 305 may be associated with representing a symbol (e.g., 1, 0, −1) of the multilevel signal. For example, if the multilevel signal is sampled (e.g., read) when the multilevel signal is at the level 305-a, a value of the multilevel signal may correspond to the value corresponding to the level 305-a (e.g., 1).

The multilevel signaling diagrams 300-a and 300-b also depict read windows for the multilevel signal. For example, a read window 310 (e.g., a read window 310-a, a read window 310-b) may be a read window for a portion (e.g., portion 206-a) of the multilevel signal associated with transitions between the level 305-a and the level 305-b. Similarly, a read window 315 (e.g., a read window 315-a, a read window 315-b) may be a read window for a portion (e.g., portion 206-b) of the multilevel signal associated with transitions between the level 305-b and the level 305-c. Each read window 310 and each read window 315 may be associated with an ideal sampling point, such that at the ideal sampling point, the respective portion of the multilevel signal may have a relatively strong SNR. For example, the read window 310-a may have an ideal sampling point 311-a and the read window 315-a may have an ideal sampling point 316-a. In some cases, the multilevel signal may be sampled at a sampling point 320, such that one or more values of the multilevel signal may be sampled (e.g., read) at the sampling point 320.

However, in the multilevel signaling diagram 300-a, the portions of the multilevel signal may be misaligned in time. For example, during generating and/or transmitting the portions of the multilevel signal, the portions of the multilevel signal may become misaligned due to timing delays in generating and/or transmitting the portions at the respective signal paths (e.g., signaling components 210-a and 210-b). For example, if multiple signal paths are used to generate different portions of the multi-level signal (e.g., as shown and described with reference to FIG. 2), the read windows may become misaligned in time. That is, without adjustable delay circuits coupled with the signal paths and configured to align the timing of the portions of the multilevel signal, the portions may be misaligned, thereby resulting in misaligned read windows 310-a and 315-a. Further, misaligned read windows 310-a and 315-a may cause the sampling points 311-a and 316-a to be misaligned in time. However, because the multilevel signal is sampled at the sampling point 320-a, if either of the sampling points 311-a and 316-a are misaligned from the sampling point 320-a, the misaligned sampling points 311-a and/or 316-a may result in an increased likelihood of sampling errors of the multilevel signal.

For example, if the sampling point 311-a and the sampling point 320-a are aligned, but the sampling point 316-a and the sampling point 320-a are misaligned, a sample of the multilevel signal at the sampling point 320-a may yield the value of the portion (e.g., the portion 206-a) associated with the read window 310-a. However, if the sampling points 311-a and 316-a are both misaligned from the sampling point 320-a, a sample of the multilevel signal at the sampling point 320-a may not yield, may misyield (e.g., misread), or may yield one of the values associated with the read windows 310-a and/or 315-a. Further, as the misalignment between the sampling points 311-a and 316-a increases, a BER may increase and an SNR of the multilevel signal may decrease, among other disadvantages.

Yet, in the multilevel signaling diagram 300-b, the portions of the multilevel signal may be aligned in time. For example, during generating and/or transmitting the portions of the multilevel signal, the portions of the multilevel signal may be aligned based on applying time adjustments to the respective signal paths associated with generating and transmitting the portions of the multilevel signal. That is, adjustable delay circuits coupled with the signal paths may be configured to align the timing of the portions of the multilevel signal, thereby resulting in aligned read windows 310-b and 315-b. Further, aligned read windows 310-b and 315-b may cause the sampling points 311-b and 316-b to be aligned in time, or more closely aligned in time. Therefore, if the sampling points 311-b and 316-b are aligned in time, the multilevel signal may be sampled at a sample point 320-b, which occurs at the alignment of the sampling points 311-b and 316-b. Otherwise, increasing an alignment of the read windows 310-b and 315-b may increase a read window margin (e.g., a sampling margin) for sampling the multilevel signal. Because the multilevel signal is sampled at a time in which the read windows 310-b and 315-b have a relatively strong SNR, the multilevel signal may be sampled with a relatively low BER.

In accordance with examples as described herein, applying individual time adjustments to the portions of the multilevel signal to align the portions may result in read window alignment of the portions. In some cases, aligning the read windows 310 and 315 of the multilevel signal may support an increased SNR and a decreased BER, which may support increased transmission speed of the multilevel signal (e.g., compared to previous implementations). Additionally, aligning the read windows 310 and 315 of the multilevel signal may improve reading the multilevel signal at a receiver of the multilevel signal, among other advantages.

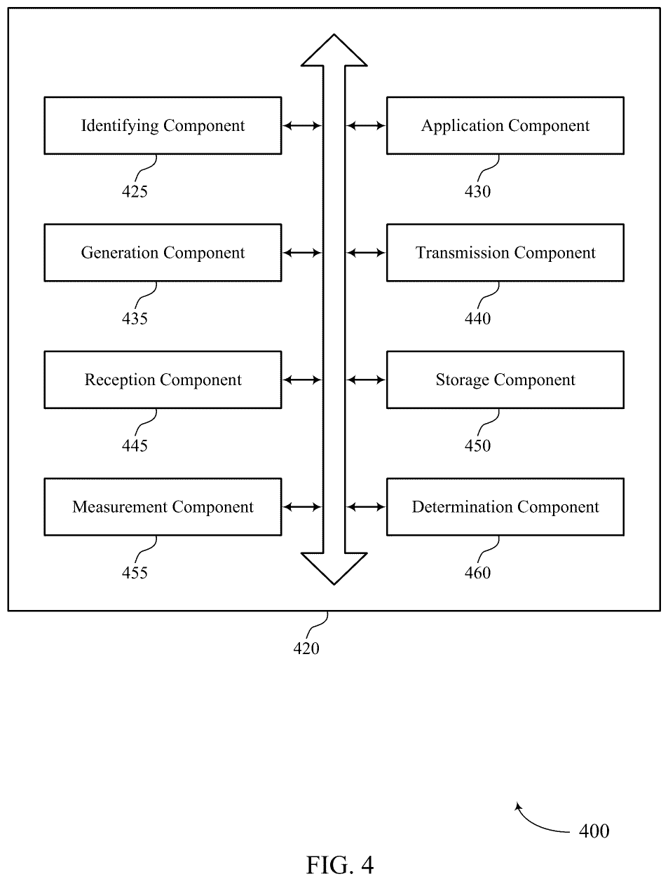

FIG. 4 shows a block diagram 400 of a memory device 420 that supports data alignment for memory in accordance with examples as disclosed herein. The memory device 420 may be an example of aspects of a memory device as described with reference to FIGS. 1 through 3. The memory device 420, or various components thereof, may be an example of means for performing various aspects of data alignment for memory as described herein. For example, the memory device 420 may include an identifying component 425, an application component 430, a generation component 435, a transmission component 440, a reception component 445, a storage component 450, a measurement component 455, a determination component 460, or any combination thereof. Each of these components, or components of subcomponents thereof (e.g., one or more processors, one or more memories), may communicate, directly or indirectly, with one another (e.g., via one or more buses).

The identifying component 425 may be configured as or otherwise support a means for identifying data for transmitting over a conductive path as a multilevel signal, the data including first data processed by a first signaling component for transmitting over the conductive path and second data processed by a second signaling component for transmitting over the conductive path. The application component 430 may be configured as or otherwise support a means for applying a first time adjustment to a clock signal received at the first signaling component. In some examples, the application component 430 may be configured as or otherwise support a means for applying a second time adjustment to the clock signal received at the second signaling component. The generation component 435 may be configured as or otherwise support a means for generating the multilevel signal based at least in part on the first signaling component generating a first portion of the multilevel signal including the first data and the second signaling component generating a second portion of the multilevel signal including the second data, where applying the first time adjustment and the second time adjustment to the clock signal is associated with aligning a timing of the first portion of the multilevel signal transmitted over the conductive path and a timing of the second portion of the multilevel signal transmitted over the conductive path.

In some examples, the transmission component 440 may be configured as or otherwise support a means for transmitting the multilevel signal via a pad contacting the conductive path based at least in part on generating the multilevel signal, the pad coupled with the first signaling component and the second signaling component.

In some examples, the first signaling component includes a first serialization component operable to serialize the first data and the second signaling component includes a second serialization component operable to serialize the second data.

In some examples, the generation component 435 may be configured as or otherwise support a means for serializing the first data based at least in part on the first time adjustment to the clock signal, where generating the first portion of the multilevel signal is based at least in part on serializing the first data. In some examples, the generation component 435 may be configured as or otherwise support a means for serializing the second data based at least in part on the second time adjustment to the clock signal, where generating the second portion of the multilevel signal is based at least in part on serializing the second data.

In some examples, to support applying the first time adjustment to the clock signal, the reception component 445 may be configured as or otherwise support a means for receiving the clock signal at a first adjustable delay circuit. In some examples, to support applying the first time adjustment to the clock signal, the application component 430 may be configured as or otherwise support a means for applying, via the first adjustable delay circuit, a first delay to the clock signal, the first delay corresponding to the first time adjustment.

In some examples, to support applying the second time adjustment to the clock signal, the reception component 445 may be configured as or otherwise support a means for receiving the clock signal at a second adjustable delay circuit. In some examples, to support applying the second time adjustment to the clock signal, the application component 430 may be configured as or otherwise support a means for applying, via the second adjustable delay circuit, a second delay to the clock signal, the second delay corresponding to the second time adjustment.

In some examples, the storage component 450 may be configured as or otherwise support a means for storing an indication of the first time adjustment and the second time adjustment in a programmable read-only memory. In some examples, the application component 430 may be configured as or otherwise support a means for where applying the first time adjustment and the second time adjustment to the clock signal is based at least in part on accessing the programmable read-only memory.

In some examples, the measurement component 455 may be configured as or otherwise support a means for measuring a misalignment between the timing of the first portion of the multilevel signal transmitted over the conductive path and the timing of the second portion of the multilevel signal transmitted over the conductive path. In some examples, the determination component 460 may be configured as or otherwise support a means for determining the first time adjustment and the second time adjustment based at least in part on measuring the misalignment. In some examples, the storage component 450 may be configured as or otherwise support a means for storing the first time adjustment and the second time adjustment in a programmable read-only memory, where applying the first time adjustment and applying the second time adjustment are based at least in part on the storing.

In some examples, the first signaling component includes a first driver operable to transmit the first portion of the multilevel signal. In some examples, the second signaling component includes a second driver operable to transmit the second portion of the multilevel signal.

In some examples, the transmission component 440 may be configured as or otherwise support a means for transmitting the first portion of the multilevel signal based at least in part on the first time adjustment to the clock signal. In some examples, the transmission component 440 may be configured as or otherwise support a means for transmitting the second portion of the multilevel signal based at least in part on the second time adjustment to the clock signal.

In some examples, to support aligning the timing of the first portion of the multilevel signal and the timing of the second portion of the multilevel signal, the generation component 435 may be configured as or otherwise support a means for increasing a read window margin between a first read window of the first portion of the multilevel signal and a second read window of the second portion of the multilevel signal.

In some examples, the multilevel signal is modulated using a modulation scheme that includes three levels.

In some examples, the described functionality of the memory device 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory device 420, or various components thereof, may be implemented at least in part by instructions (e.g., stored in memory, non-transitory computer-readable medium) executable by such at least one processor.

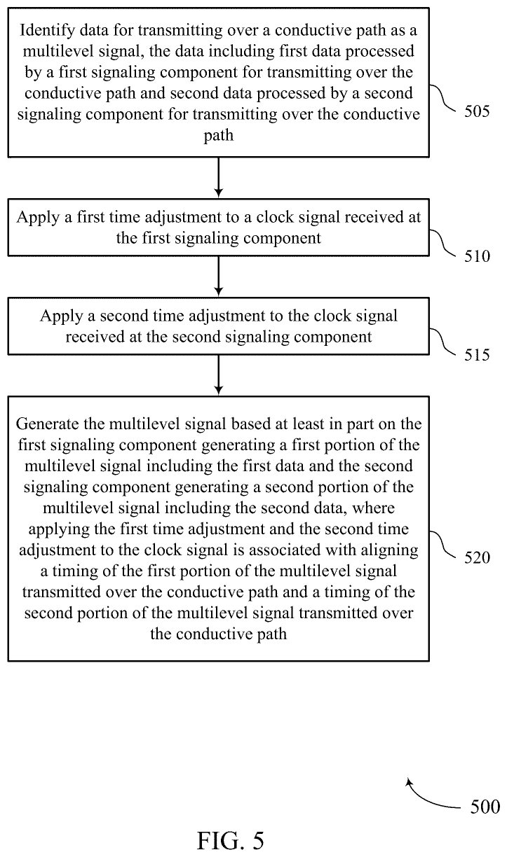

FIG. 5 shows a flowchart illustrating a method 500 that supports data alignment for memory in accordance with examples as disclosed herein. The operations of method 500 may be implemented by a memory device or its components as described herein. For example, the operations of method 500 may be performed by a memory device as described with reference to FIGS. 1 through 4. In some examples, a memory device may execute a set of instructions to control the functional elements of the device to perform the described functions. Additionally, or alternatively, the memory device may perform aspects of the described functions using special-purpose hardware.

At 505, the method may include identifying data for transmitting over a conductive path as a multilevel signal, the data including first data processed by a first signaling component for transmitting over the conductive path and second data processed by a second signaling component for transmitting over the conductive path. In some examples, aspects of the operations of 505 may be performed by an identifying component 425 as described with reference to FIG. 4.

At 510, the method may include applying a first time adjustment to a clock signal received at the first signaling component. In some examples, aspects of the operations of 510 may be performed by an application component 430 as described with reference to FIG. 4.

At 515, the method may include applying a second time adjustment to the clock signal received at the second signaling component. In some examples, aspects of the operations of 515 may be performed by an application component 430 as described with reference to FIG. 4.

At 520, the method may include generating the multilevel signal based at least in part on the first signaling component generating a first portion of the multilevel signal including the first data and the second signaling component generating a second portion of the multilevel signal including the second data, where applying the first time adjustment and the second time adjustment to the clock signal is associated with aligning a timing of the first portion of the multilevel signal transmitted over the conductive path and a timing of the second portion of the multilevel signal transmitted over the conductive path. In some examples, aspects of the operations of 520 may be performed by a generation component 435 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for identifying data for transmitting over a conductive path as a multilevel signal, the data including first data processed by a first signaling component for transmitting over the conductive path and second data processed by a second signaling component for transmitting over the conductive path; applying a first time adjustment to a clock signal received at the first signaling component; applying a second time adjustment to the clock signal received at the second signaling component; and generating the multilevel signal based at least in part on the first signaling component generating a first portion of the multilevel signal including the first data and the second signaling component generating a second portion of the multilevel signal including the second data, where applying the first time adjustment and the second time adjustment to the clock signal is associated with aligning a timing of the first portion of the multilevel signal transmitted over the conductive path and a timing of the second portion of the multilevel signal transmitted over the conductive path.

Aspect 2: The method, apparatus, or non-transitory computer-readable medium of aspect 1, further including operations, features, circuitry, logic, means, or instructions, or any combination thereof for transmitting the multilevel signal via a pad contacting the conductive path based at least in part on generating the multilevel signal, the pad coupled with the first signaling component and the second signaling component.

Aspect 3: The method, apparatus, or non-transitory computer-readable medium of any of aspects 1 through 2, where the first signaling component includes a first serialization component operable to serialize the first data and the second signaling component includes a second serialization component operable to serialize the second data.

Aspect 4: The method, apparatus, or non-transitory computer-readable medium of aspect 3, further including operations, features, circuitry, logic, means, or instructions, or any combination thereof for serializing the first data based at least in part on the first time adjustment to the clock signal, where generating the first portion of the multilevel signal is based at least in part on serializing the first data and serializing the second data based at least in part on the second time adjustment to the clock signal, where generating the second portion of the multilevel signal is based at least in part on serializing the second data.

Aspect 5: The method, apparatus, or non-transitory computer-readable medium of any of aspects 1 through 4, where applying the first time adjustment to the clock signal includes operations, features, circuitry, logic, means, or instructions, or any combination thereof for receiving the clock signal at a first adjustable delay circuit and applying, via the first adjustable delay circuit, a first delay to the clock signal, the first delay corresponding to the first time adjustment.

Aspect 6: The method, apparatus, or non-transitory computer-readable medium of any of aspects 1 through 5, where applying the second time adjustment to the clock signal includes operations, features, circuitry, logic, means, or instructions, or any combination thereof for receiving the clock signal at a second adjustable delay circuit and applying, via the second adjustable delay circuit, a second delay to the clock signal, the second delay corresponding to the second time adjustment.

Aspect 7: The method, apparatus, or non-transitory computer-readable medium of any of aspects 1 through 6, further including operations, features, circuitry, logic, means, or instructions, or any combination thereof for storing an indication of the first time adjustment and the second time adjustment in a programmable read-only memory and where applying the first time adjustment and the second time adjustment to the clock signal is based at least in part on accessing the programmable read-only memory.

Aspect 8: The method, apparatus, or non-transitory computer-readable medium of any of aspects 1 through 7, further including operations, features, circuitry, logic, means, or instructions, or any combination thereof for measuring a misalignment between the timing of the first portion of the multilevel signal transmitted over the conductive path and the timing of the second portion of the multilevel signal transmitted over the conductive path; determining the first time adjustment and the second time adjustment based at least in part on measuring the misalignment; and storing the first time adjustment and the second time adjustment in a programmable read-only memory, where applying the first time adjustment and applying the second time adjustment are based at least in part on the storing.

Aspect 9: The method, apparatus, or non-transitory computer-readable medium of any of aspects 1 through 8, where the first signaling component includes a first driver operable to transmit the first portion of the multilevel signal and the second signaling component includes a second driver operable to transmit the second portion of the multilevel signal.

Aspect 10: The method, apparatus, or non-transitory computer-readable medium of any of aspects 1 through 9, further including operations, features, circuitry, logic, means, or instructions, or any combination thereof for transmitting the first portion of the multilevel signal based at least in part on the first time adjustment to the clock signal and transmitting the second portion of the multilevel signal based at least in part on the second time adjustment to the clock signal.

Aspect 11: The method, apparatus, or non-transitory computer-readable medium of any of aspects 1 through 10, where aligning the timing of the first portion of the multilevel signal and the timing of the second portion of the multilevel signal includes operations, features, circuitry, logic, means, or instructions, or any combination thereof for increasing a read window margin between a first read window of the first portion of the multilevel signal and a second read window of the second portion of the multilevel signal.

Aspect 12: The method, apparatus, or non-transitory computer-readable medium of any of aspects 1 through 11, where the multilevel signal is modulated using a modulation scheme that includes three levels.

It should be noted that the methods described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

As used herein, including in the claims, the article “a” before a noun is open-ended and understood to refer to “at least one” of those nouns or “one or more” of those nouns. Thus, the terms “a,” “at least one,” “one or more,” and “at least one of one or more” may be interchangeable. For example, if a claim recites “a component” that performs one or more functions, each of the individual functions may be performed by a single component or by any combination of multiple components. Thus, “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.”

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
at least one memory device; and
at least one controller coupled with the at least one memory device and configured to cause the apparatus to:
identify data for transmitting over a conductive path as a multilevel signal, the data comprising first data processed by a first signaling component for transmitting over the conductive path and second data processed by a second signaling component for transmitting over the conductive path;
apply a first time adjustment to a clock signal received at the first signaling component;
apply a second time adjustment to the clock signal received at the second signaling component; and
generate the multilevel signal based at least in part on the first signaling component generating a first portion of the multilevel signal comprising the first data and the second signaling component generating a second portion of the multilevel signal comprising the second data, wherein applying the first time adjustment and the second time adjustment to the clock signal is associated with aligning a timing of the first portion of the multilevel signal transmitted over the conductive path and a timing of the second portion of the multilevel signal transmitted over the conductive path.

2. The apparatus of claim 1, wherein the at least one controller is further configured to cause the apparatus to:
transmit the multilevel signal via a pad contacting the conductive path based at least in part on generating the multilevel signal, the pad coupled with the first signaling component and the second signaling component.

3. The apparatus of claim 1, wherein the first signaling component comprises a first serialization component operable to serialize the first data and the second signaling component comprises a second serialization component operable to serialize the second data.

4. The apparatus of claim 3, wherein the at least one controller is further configured to cause the apparatus to:
serialize the first data based at least in part on the first time adjustment to the clock signal, wherein generating the first portion of the multilevel signal is based at least in part on serializing the first data; and
serialize the second data based at least in part on the second time adjustment to the clock signal, wherein generating the second portion of the multilevel signal is based at least in part on serializing the second data.

5. The apparatus of claim 1, wherein applying the first time adjustment to the clock signal is configured to cause the apparatus to:
receive the clock signal at a first adjustable delay circuit; and
apply, via the first adjustable delay circuit, a first delay to the clock signal, the first delay corresponding to the first time adjustment.

6. The apparatus of claim 1, wherein applying the second time adjustment to the clock signal is configured to cause the apparatus to:
receive the clock signal at a second adjustable delay circuit; and
apply, via the second adjustable delay circuit, a second delay to the clock signal, the second delay corresponding to the second time adjustment.

7. The apparatus of claim 1, wherein the at least one controller is further configured to cause the apparatus to:
store an indication of the first time adjustment and the second time adjustment in a programmable read-only memory; and
wherein apply the first time adjustment and the second time adjustment to the clock signal is based at least in part on accessing the programmable read-only memory.

8. The apparatus of claim 1, wherein the at least one controller is further configured to cause the apparatus to:
measure a misalignment between the timing of the first portion of the multilevel signal transmitted over the conductive path and the timing of the second portion of the multilevel signal transmitted over the conductive path;
determine the first time adjustment and the second time adjustment based at least in part on measuring the misalignment; and
store the first time adjustment and the second time adjustment in a programmable read-only memory, wherein applying the first time adjustment and applying the second time adjustment are based at least in part on the storing.

9. The apparatus of claim 1, wherein:
the first signaling component comprises a first driver operable to transmit the first portion of the multilevel signal, and
the second signaling component comprises a second driver operable to transmit the second portion of the multilevel signal.

10. The apparatus of claim 1, wherein the at least one controller is further configured to cause the apparatus to:
transmit the first portion of the multilevel signal based at least in part on the first time adjustment to the clock signal; and
transmit the second portion of the multilevel signal based at least in part on the second time adjustment to the clock signal.

11. The apparatus of claim 1, wherein aligning the timing of the first portion of the multilevel signal and the timing of the second portion of the multilevel signal is configured to cause the apparatus to:
increase a read window margin between a first read window of the first portion of the multilevel signal and a second read window of the second portion of the multilevel signal.

12. The apparatus of claim 1, wherein the multilevel signal is modulated using a modulation scheme that comprises three levels.

13. A non-transitory computer-readable medium storing code, the code comprising instructions executable by a processor to:
identify data for transmitting over a conductive path as a multilevel signal, the data comprising first data processed by a first signaling component for transmitting over the conductive path and second data processed by a second signaling component for transmitting over the conductive path;
apply a first time adjustment to a clock signal received at the first signaling component;
apply a second time adjustment to the clock signal received at the second signaling component; and
generate the multilevel signal based at least in part on the first signaling component generating a first portion of the multilevel signal comprising the first data and the second signaling component generating a second portion of the multilevel signal comprising the second data, wherein applying the first time adjustment and the second time adjustment to the clock signal is associated with aligning a timing of the first portion of the multilevel signal transmitted over the conductive path and a timing of the second portion of the multilevel signal transmitted over the conductive path.

14. The non-transitory computer-readable medium of claim 13, wherein the instructions are further executable by the processor to:
transmit the multilevel signal via a pad contacting the conductive path based at least in part on generating the multilevel signal, the pad coupled with the first signaling component and the second signaling component.

15. The non-transitory computer-readable medium of claim 13, wherein the first signaling component comprises a first serialization component operable to serialize the first data based at least in part on the first time adjustment to the clock signal and the second signaling component comprises a second serialization component operable to serialize the second data based at least in part on the second time adjustment to the clock signal.

16. The non-transitory computer-readable medium of claim 13, wherein the instructions to apply the first time adjustment to the clock signal are executable by the processor to:
receive the clock signal at a first adjustable delay circuit; and
apply, via the first adjustable delay circuit, a first delay to the clock signal, the first delay corresponding to the first time adjustment; and
wherein the instructions to apply the second time adjustment to the clock signal are executable by the processor to:
receive the clock signal at a second adjustable delay circuit; and
apply, via the second adjustable delay circuit, a second delay to the clock signal, the second delay corresponding to the second time adjustment.

17. The non-transitory computer-readable medium of claim 13, wherein the instructions are further executable by the processor to:
store an indication of the first time adjustment and the second time adjustment in a programmable read-only memory; and
wherein apply the first time adjustment and the second time adjustment to the clock signal is based at least in part on accessing the programmable read-only memory.

18. The non-transitory computer-readable medium of claim 13, wherein the instructions are further executable by the processor to:
measure a misalignment between the timing of the first portion of the multilevel signal transmitted over the conductive path and the timing of the second portion of the multilevel signal transmitted over the conductive path;
determine the first time adjustment and the second time adjustment based at least in part on measuring the misalignment; and
store the first time adjustment and the second time adjustment in a programmable read-only memory, wherein applying the first time adjustment and applying the second time adjustment are based at least in part on the storing.

19. The non-transitory computer-readable medium of claim 13, wherein:
the first signaling component comprises a first driver operable to transmit the first portion of the multilevel signal based at least in part on the first time adjustment to the clock signal, and
the second signaling component comprises a second driver operable to transmit the second portion of the multilevel signal based at least in part on the second time adjustment to the clock signal.

20. A method, comprising:
identifying data for transmitting over a conductive path as a multilevel signal, the data comprising first data processed by a first signaling component for transmitting over the conductive path and second data processed by a second signaling component for transmitting over the conductive path;
applying a first time adjustment to a clock signal received at the first signaling component;
applying a second time adjustment to the clock signal received at the second signaling component; and
generating the multilevel signal based at least in part on the first signaling component generating a first portion of the multilevel signal comprising the first data and the second signaling component generating a second portion of the multilevel signal comprising the second data, wherein applying the first time adjustment and the second time adjustment to the clock signal is associated with aligning a timing of the first portion of the multilevel signal transmitted over the conductive path and a timing of the second portion of the multilevel signal transmitted over the conductive path.
